(19) United States
(12) Patent Application Publication
(10) Pub. No.: US 2010/0244270 A1
(43) Pub. Date: Sep. 30, 2010

(54) MANUFACTURING METHOD OF SEMICONDUCTOR DEVICE AND SEMICONDUCTOR DEVICE

(75) Inventors: Hiroshi Asami, Shizuoka (JP); Masaki Hatano, Kanagawa (JP); Akihiro Morimoto, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/727,804

(22) Filed: Mar. 19, 2010

(30) Foreign Application Priority Data
Mar. 30, 2009 (JP) 2009-081097

(51) Int. Cl. H01L 23/48; H01L 21/50

(52) U.S. Cl. 257/773; 438/64; 257/E21.499; 257/E23.011

(57) ABSTRACT

A semiconductor device includes: a component substrate of a semiconductor device; electrode pads provided on one surface of the component substrate; a support plate material reinforcing the component substrate; via holes made in the support plate material; a conducting material filled in the via holes; and a joining member interposed between the electrode pads and the conducting material and joining the component substrate and the support plate material.

### BACKGROUND OF THE INVENTION

1. Field of the Invention

The present invention relates to a manufacturing method of a semiconductor device and a semiconductor device manufactured by this manufacturing method.

2. Description of the Related Art

Recently, as an example of a semiconductor device, an image sensor (hereinafter, referred to also as the imaging device), such as a CMOS (Complimentary Metal Oxide Semiconductor) image sensor and a CCD (Charge Coupled Device) image sensor, has been used extensively.

In order to increase the sensitivity of the image sensor, it is effective to use, for example, an SOI (Silicon On Insulator) substrate and to dispose photodetectors on the surface thereof in an exposed manner. It should be noted, however, that the substrate becomes as thin as 20 μm or thinner when polishing or Si etching is applied to expose the photodetectors and this thinness makes handling (in particular, substrate handling) difficult. Such being the case, in order to achieve the configuration to expose the photodetectors, a manufacturing method of laminating a support plate material, such as glass and silicon, to the SOI substrate with a resin adhesive before the thinning of the SOI substrate is adopted. Such a manufacturing method is described, for example, in JP-A-2003-171624, JP-A-2005-191550, and JP-A-2004-311744.

### SUMMARY OF THE INVENTION

Incidentally, a smaller and lighter image sensor is becoming more desirable. In order to achieve a reduction in size and weight, it is effective to form external terminals on the back side of the sensor light receiving surface so that a signal can be extracted from the back side (that is, the sensor bottom surface side).

In the case of the image sensor fabricated by laminating the support plate material to the SOI substrate, however, it is difficult to directly pull out the terminals on the support plate material side.

In the case of the configuration in which the terminals are not pulled out on the support plate material side, sensor mounting is carried out by wire bonding. Accordingly, it becomes necessary to secure a bonding pad region. Hence, in comparison with a case where the external terminals are formed, it becomes difficult to obtain a smaller sensor. It is therefore likely that the theoretical yield becomes poor and the manufacturing costs are increased.

Even with the configuration in which the support plate material is laminated to the SOI substrate, the terminals can be pulled out on the support plate material side by drilling holes through the support plate material from the support plate material side after the lamination. When holes are drilled through the support plate material after the lamination of the support plate material, however, the SOI substrate to which the support plate material is joined may be susceptible to adverse influences. To be more concrete, it is likely that adverse influences of heat and contamination generated at the time of drilling are given to the SOI substrate and optical components, such as an on-chip color filter (hereinafter, abbreviated to OCCF), formed on the SOI substrate.

It is desirable to provide a manufacturing method of a semiconductor device not only to achieve a reduction in size and weight by pulling out the terminals on the side of the support plate material while ensuring the strength of the component substrate using the support plate material but also to avoid adverse influences of the terminal pulling-out processing from being given to the component substrate, and a semiconductor device.

According to an embodiment of the present invention, there is provided a manufacturing method of a semiconductor device including the steps of: forming a component substrate of a semiconductor device provided with electrode pads on one surface thereof; making via holes in a support plate material reinforcing the component substrate and filling a conducting material in the via holes; and joining the component substrate and the support plate material in such a manner that the electrode pads on the component substrate and the conducting material filled in the via holes in the support plate material are electrically connected to each other.

With the method of manufacturing a semiconductor device having the procedure as above, the component substrate of the semiconductor device is reinforced by the support plate material because of the joining step. Also, because not only the via holes are made in the support plate material but also the conducting material is filled in the via holes in the plate material forming step, the terminals can be pulled out on the side of the support plate material via the conducting material. Moreover, because the joining step is carried out after the plate material forming step, influences of the making of the via holes in the support plate material and the filling of the conducting material will not be given to the component substrate to which the support plate material is joined.

According to an embodiment of the present invention, it becomes possible to achieve a smaller and lighter semiconductor device by pulling out the terminals on the side of the support plate material while ensuring the strength of the component substrate using the support plate material. Further, even in this case, adverse influences of the terminal pulling-out processing applied to the support plate material will not be given to the component substrate. Hence, there can be achieved advantages that the theoretical yield, the manufacturing costs, and the fabrication yield when manufacturing the semiconductor device, the reliability of the semiconductor device, and the degree of freedom in selecting the treatment processes can be enhanced in comparison with the related art.

### BRIEF DESCRIPTION OF THE DRAWINGS

FIGS. 1A to 1H are views used to describe a concrete example of the procedure (first half) of a manufacturing method of a semiconductor device according to an embodiment of the present invention;

FIGS. 2A to 2E are views used to describe the concrete example of the procedure (second half) of the manufacturing method of the semiconductor device according to an embodiment of the present invention; and

FIGS. 3A and 3B are views used to describe an example of an outside wall portion used to fill an insulating resin material.

### DETAILED DESCRIPTION OF THE INVENTION

Hereinafter, a manufacturing method of a semiconductor device and a semiconductor device according to an embodiment of the present invention will be described with reference to the drawings.

### [Basic Procedure of Manufacturing Method of Semiconductor Device]

Initially, a manufacturing method of a semiconductor device will be described.

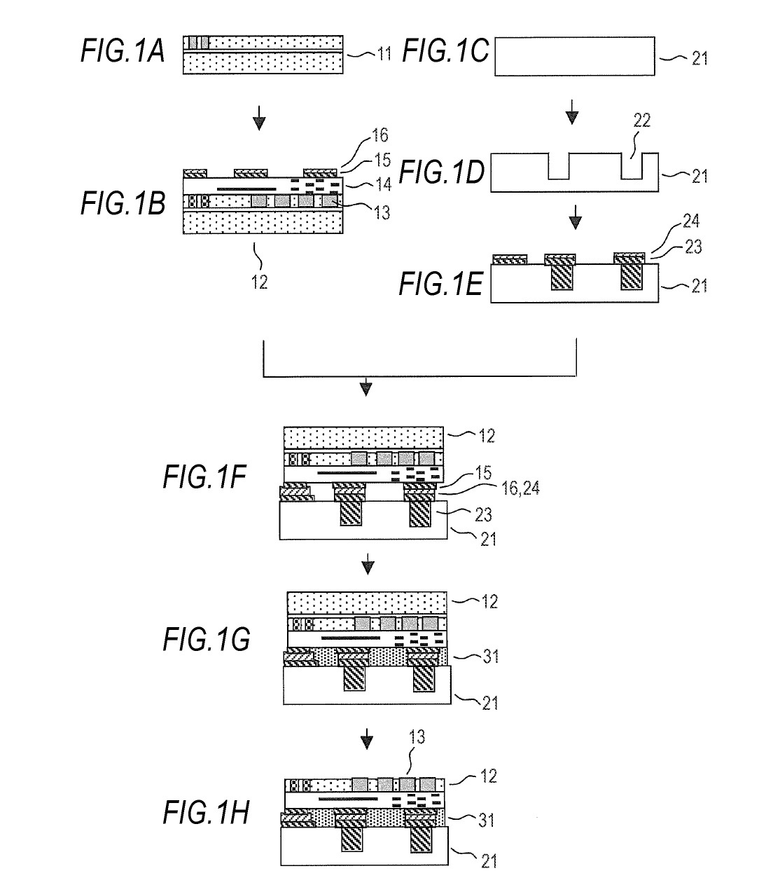

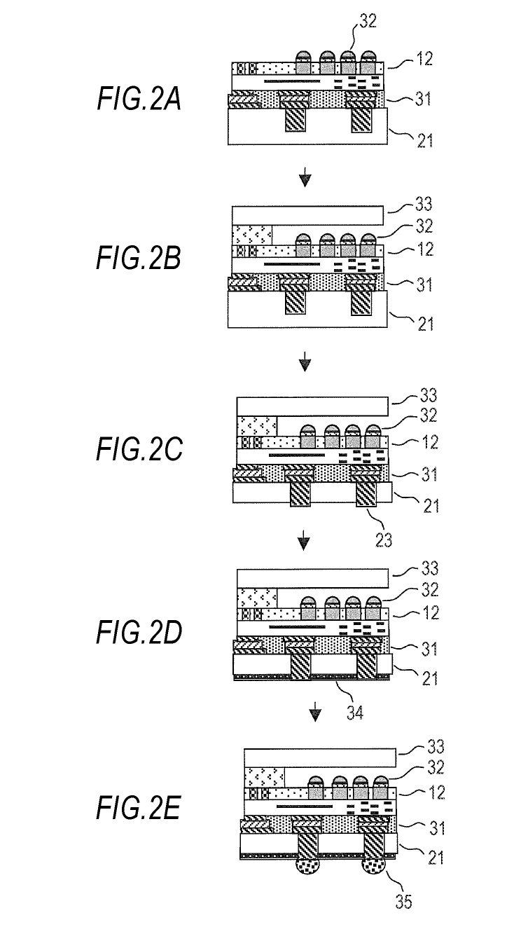

FIGS. 1A to 1H and FIGS. 2A to 2E are views used to describe a concrete example of a manufacturing method of a semiconductor device according to an embodiment of the present invention. The drawings show the manufacturing procedure of a CMOS image sensor as an example of the semiconductor device.

When the CMOS image sensor is manufactured, as is shown in FIG. 1A, an SOI substrate 11 is prepared.

Subsequently, as is shown in FIG. 1B, a component substrate 12 of the CMOS image sensor is formed using the SOI substrate 11.

The component substrate 12 is provided with photodetectors 13, a wiring layer 14, and so forth. Further, electrode pads 15 that electrically conduct with the photodetectors 13 and the wiring layer 14 and extract a signal are provided on one surface (the top surface in the drawing) of the component substrate 12. The electrode pads 15 may be formed, for example, of copper (Cu) with a thickness of 5 μm. In addition, bumps 16 made, for example, of tin (Sn) and having a thickness of 2 μm are formed on the electrode pads 15.

That is to say, the step performed at this stage is to form the component substrate 12 of the CMOS image sensor provided with the electrode pads 15 and the bumps 16 on one surface thereof using the SOI substrate 11. Because known arts are available to the process of forming the component substrate 12, a detailed description is omitted herein.

Apart from the step of forming the component substrate 12 described above, as is shown in FIG. 1C, a support plate material 21 to reinforce the component substrate 12 is prepared. The support plate material 21 can be, for example, a 550-μm-thick silicon (Si) substrate.

When the support plate material 21 is prepared, as is shown in FIG. 1D, via holes 22 are made in the support plate material 21. It should be noted that the via holes 22 are made as non-penetrating holes. The positions at which to make the via holes 22 correspond to the positions of the electrode pads 15 on the component substrate 12. To be more concrete, the via holes 22 may be made, for example, to have a diameter of 30 μm and a depth of 170 μm at a pitch of 200 μm.

After the via holes 22 are made, as is shown in FIG. 1E, a conducting material 23 is filled in the via holes 22. To be more concrete, a 120-nm-thick SiO₂ film is formed on the surface layer of the support plate material 21 and inside the via holes 22 by the thermally oxidized film treatment. Further, Ti 200 nm/Cu 350 nm is applied as a seed metal for plating. Filling of the conducting material 23 made of Cu is then carried out by filling Cu inside the via holes 22 and forming a 10-μm-thick Cu layer on the surface layer. Also, a solder layer 24 made, for example, of Sn3Ag with a thickness of 10 μm is formed on the conducting material 23.

Thereafter, the plating resist is removed and the seed metal is removed by dissolving with a liquid exclusively used for the seed metal.

That is to say, the step performed at this stage is to make the non-penetrating via holes 22 in the support plate material 21 used to reinforce the component substrate 12 and to fill the conducting materials 23 in the via holes 22. The step of forming the support plate material 21 can be performed after the step of forming the component substrate 12 described above, before the step of forming the component substrate 12, or simultaneously in parallel with the step of forming the component substrate 12.

After the component substrate 12 of the CMOS image sensor 12 is formed and the support plate material 21 in which the conducting material 23 is filled in the via holes 22 is formed, as is shown in FIG. 1F, the component substrate 12 and the support plate material 21 are joined. This joining is carried out in such a manner that the electrode pads 15 on the component substrate 12 and the conducting material 23 filled in the via holes 22 in the support plate material 21 are electrically connected to each other. To be more concrete, by dissolving the bumps 16 on the electrode pads 15 and the solder layer 24 on the conducing material 23 while the electrode pads 15 and the conducting material 23 oppose and abut on each other, the component substrate 12 and the support plate material 21 are joined.

That is to say, the step performed at this stage is to join the component substrate 12 and the support plate material 21 while ensuring the electrical connection between the electrode pads 15 on the component substrate 12 and the conducting material 23 in the support plate material 21.

The joining of the component substrate 12 and the support plate material 21 in this instance can be carried out at a temperature of about 260° C. using, for example, non-residue flux. Alternatively, the joining may be carried out by removing an oxide film in a plasma reflow furnace.

In addition, a 10-μm-thick IMC (MP≧350° C.) may be formed by applying a Cu diffusion treatment to the joined portion, for example, by heating at 220° C. after the component substrate 12 and the support plate material 21 are joined.

Herein, Sn3Ag is used as the solder layer 24 and MP is increased by IMC growth by way of example. However, it is also possible to use, for example, Au20Sn or SnIn-based low-temperature solder (for example, about 175° C.).

Thereafter, as is shown in FIG. 1G, an insulating resin material 31 is filled in a clearance between the component substrate 12 and the support plate material 21 joined in the joining step described above. The clearance between the component substrate 12 and the support plate material 21 is, for example, about 10 μm across. The insulating resin material 31 filled in such a microscopic clearance can be, for example, a thermoplastic resin material. To be more concrete, a thermoplastic fluorine resin material having a melting point of 270° C. is used as the insulating resin material 31 and this thermoplastic fluorine resin material is adjusted to have a low viscosity at 300° C. The thermoplastic fluorine resin material in this state is then vacuum filled in the clearance between the component substrate 12 and the support plate material 21 and the thermoplastic fluorine resin material is cured later.

Although it will be described in detail below, when the insulating resin material 31 is filled in the clearance between the component substrate 12 and the support plate 21, it is desirable to use an outside wall portion 41 surrounding the filling region of the insulating rein material 31. More specifically, before the step of filling the insulating resin material 31, the outside wall forming step of forming the outside wall portion 41 surrounding the filling region of the insulating resin material 31 is carried out. The filling of the insulating resin material 31 is carried out using the outside wall portion 41 formed in the outside wall forming step. The outside wall forming step will be described in detail below.

After the insulating resin material 31 is filled, as is shown in FIG. 1H, polishing or Si etching is applied to the component substrate 12 to which the support plate material 21 is joined, so that the photodetectors 13 are exposed. Consequently, the component substrate 12 becomes, for example, as thin as 7 to 10 μm.

Thereafter, as is shown in FIG. 2A, optical components 32, such as an OCCF and an on-chip lens (hereinafter, also abbreviated to OCL), are provided so as to cover the exposed surface side of the photodetectors 13.

Further, as is shown in FIG. 2B, a seal glass 33 is disposed on the sensor light receiving side so as to cover the top surface side of the optical components 32.

That is to say, after the joining step described above, the step of mounting various optical components on the component substrate 12 is carried out. Because known arts are available to the forming process of various optical components, a detailed description is omitted herein.

Thereafter, as is shown in FIG. 2C, the support plate material 21 is made thinner from the side of the support plate material 21, so that the conducting material 23 filled in the non-penetrating via holes 22 is exposed. To be more concrete, for example, polishing plus Si dissolving are applied to the support plate material 21, so that the conducting material 23 in the via holes 22 is exposed on the back side of the sensor light receiving surface (the bottom surface side in the drawing). The exposed conducting material 23 has a diameter, for example, of about 30 to 100 μm.

After the exposing step described above, as is shown in FIG. 2D, an insulating resin layer 34 is formed on the exposed side of the support plate material 21. The plate thickness of the support plate material 21 including the insulating resin layer 34 after the thinning is, for example, about 100 to 150 μm.

Further, as is shown in FIG. 2E, external terminals 35 are formed by applying SnBi-based low-temperature solder to the exposed portion of the conducting material 23.

The external terminals 35 may be formed using other known arts. For example, besides the plating method, the external terminals 35 can be formed by methods, such as alloy welding, printing plus reflow, and lift off.

### [Procedure of Filling of Insulating Resin Material]

A method of filling the insulating resin material 31 in a clearance between the component substrate 12 and the support plate material 21 will now be described in detail.

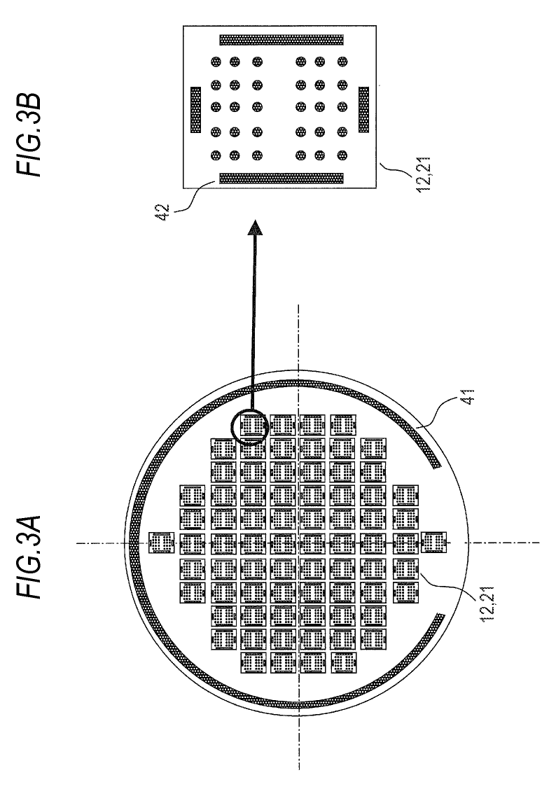

FIGS. 3A and 3B are views used to describe an example of the outside wall portion used when the insulating resin material is filled.

During the manufacturing process of the CMOS image sensor described above, the outside wall forming step is carried out, as has been described, before the step of filling the insulating resin material 31.

In the outside wall forming step, for example, as is shown in FIG. 3A, the outside wall portion 41 that surrounds the filling region of the insulating resin material 31 and opens in part for the filling of the insulating resin material 31 is formed. The forming material and the forming shape of the outside wall portion 41 are not particularly limited.

Also, for example, as is shown in FIG. 3B, piece fixed reinforcing ribs 42 functioning as reinforcing materials until the insulating resin material 31 is filled may be provided correspondingly to the respective forming regions of the component substrates 12 when the outside wall portion 41 is formed.

After the outside wall portion 41 is formed, the insulating resin material 31 in a low viscosity state is injected through the opening portion of the outside wall portion 41 in the step of filling the insulating resin material 31 that is carried out after the outside wall portion 41 is formed. In this instance, the outer peripheral side of the filling region of the insulating resin material 31 is surrounded by the outside wall portion 41. Hence, even when the clearance between the component substrate 12 and the support plate material 21 is narrow, the insulating resin material 31 in a low viscosity state injected through the opening portion penetrates thoroughly into the filling region by capillarity independently of a gravitational force and the right, left, up, and down directions.

By using the outside wall portion 41 surrounding the filling region of the insulating resin material 31 when the insulating resin material 31 is filled in the clearance between the component substrate 12 and the support plate material 21 in this manner, the insulating resin material 31 penetrates thoroughly into the filling region. It thus becomes possible to carry out the filling of the insulating resin material 31 in a reliable manner.

### [Example of Configuration of Semiconductor Device]

The configuration of the CMOS image sensor manufactured by the manufacturing method as above will now be described with reference to FIG. 2E.

As is shown in FIG. 2E, the CMOS image sensor manufactured by the procedure described above is fabricated by joining the support plate material 21 to the component substrate 12 formed using the SOI substrate. Accordingly, even when the component substrate 12 has to be made thinner during the manufacturing process, because the component substrate 12 is reinforced by the support plate material 21, handling of the component substrate 12 (in particular, substrate handling) will not become difficult.

Also, although the CMOS image sensor manufactured by the procedure described above is fabricated by joining the support plate material 21 to the component substrate 12, the external terminals 35 are formed on the back side of the sensor light receiving surface, that is, on the bottom surface side of the support plate material 21. The external terminals 35 electrically conduct with the electrode pads 15 on the component substrate 12 through the via holes 22 and the conducting material 23 in the support plate material 21. Hence, even when the support plate material 21 is joined, a signal can be extracted on the side of the support plate material 21, which is effective in achieving a smaller and lighter image sensor.

Further, the CMOS image sensor manufactured by the procedure described above is fabricated by joining the support plate material 21 to the component substrate 12 after the via holes 22 are made in the support plate material 21 and the conducting material 23 is filled therein. That is to say, even after the component substrate 12 and the support plate material 21 are joined, a layer of a joining member that joins the electrode pads 15 on the component substrate 12 and the conducting material 23 in the support plate material 21 which is interposed in between. To be more concrete, the bumps 16 and the solder layer 24 are interposed as the joining member.

Accordingly, in the CMOS image sensor of the configuration in which the joining member is interposed, even when a signal is extracted on the side of the support plate material 21, influences of the making of the via holes 22 in the support plate material 21 and the filling of the conducting material 23 therein will not be given to the side of the component substrate 12. To be more concrete, adverse influences of heat, contamination, chemicals, and so forth possibly generated during the working process, such as the making of the via holes 22 and the filling of the conducting material 23, will not be given to the component substrate 12 and the optical components 32 mounted on the component substrate 12.

Different from the configuration according to an embodiment of the present invention, in the manufacturing method of the related art in which the support plate material is laminated merely with a resin adhesive, the treatment processes are limited by the heat resistance of the resin adhesive. By contrast, when joining is carried out by interposing the joining member as in the configuration according to an embodiment of the present invention, a temperature width in the treatment processes including the joining of the support plate material 21 can be widened to a high temperature side in comparison with a case in the related art.

Moreover, portions joined by interposing the joining member are scattered within the surfaces of the component substrate 12 and the support plate material 21. Hence, even when thermal expansion coefficients of the joining member and the conducting material 23 are different from thermal expansion coefficients of the component substrate 12 and the support plate material 21, the base material of the component substrate 12 will not undergo noticeable deformation after the support plate material 21 is joined.

As has been described, in the CMOS image sensor of the configuration according to an embodiment of the present invention, a reduction in size and weight can be achieved by pulling out the terminals on the side of the support plate material 21 while ensuring the strength of the component substrate 12 using the support plate material 21. Moreover, even in this case, the terminal pulling-out processing will not give adverse influences to the component substrate 12.

In view of the foregoing, because the component substrate 12 and the support plate material 21 are joined by interposing the joining member in the CMOS image sensor of the configuration according to an embodiment of the present invention, it can be said that the theoretical yield, the manufacturing costs, the fabrication yield, the degree of freedom in selecting the treatment processes, and the reliability are enhanced in comparison with the prior art.

In particular, with the configuration in which the joining member is interposed, by making the non-penetrating via holes 22 in the support plate material 21 and making the support plate material 21 thinner after it is joined to the component substrate 12 for the conducting material 23 to be exposed, the following advantages can be obtained. That is, because the via holes 22 are formed as non-penetrating holes, it is possible to suppress contamination caused by metal inside the via holes 22 in the joining process of the support plate material 21 at a low level. Also, in a case where the plate thickness of the support plate material 21 before the thinning is large or the diameter of the via holes 22 is small, the via holes 22 can be made more readily than in a case where the via holes 22 are made as penetrating holes.

With the configuration in which the joining member is interposed, by filling the insulating resin material 31 in a clearance between the component substrate 12 and the support plate material 21, the following advantages can be obtained. That is, owing to the spot joining by the joining member present at points scattered within the surface and the clearance filling effect by the low elastic insulating resin material 31, warping is lessened in comparison with a case in the related art in which lamination is carried out merely with a resin adhesive and a dimensional distortion after the thinning of the component substrate 12 can be reduced to half. Also, owing to the clearance filling effect by the insulating resin material 31, better impact resistance can be expected in comparison with a case where the insulating resin material 31 is not filled in the clearance. Consequently, it becomes possible to increase the mechanical strength of the CMOS image sensor. Further, because adhesion with a resin adhesive is not adopted, not only thermosetting resin, but also thermoplastic resin, such as a liquid crystal polymer, becomes available as the insulating resin material 31.

In a case where the insulating resin material 31 is filled in the clearance between the component substrate 12 and the support plate material 21, the insulating resin material 31 penetrates thoroughly into the filling region of the insulating resin material 31 by using the outside wall portion 41 surrounding the filling region. It thus becomes possible to fill the insulating resin material 31 in the clearance between the component substrate 12 and the support plate material 21 in a reliable manner.

In a case where the piece fixed reinforcing ribs 42 are provided in addition to the outside wall portion 41, the piece fixed reinforcing ribs 42 can confer a strength high enough to withstand a mechanical impact caused by the dicing. The dicing process to obtain piece-wise individual sensors can be therefore carried out without any problem.

A suitable concrete example has been described herein as an embodiment of the present invention. It should be appreciated, however, that the present invention is not limited to the content described above.

For example, the CMOS image sensor has been described herein as an example of the semiconductor device. However, besides the CMOS image sensor, an embodiment of the present invention is applicable in totally the same manner to semiconductor devices manufactured by a so-called semiconductor process. It should be noted, however, that the optical components 32, such as the OCCF and the OCL, are susceptible to heat are disposed on the component substrate 12 in the case of the CMOS image sensor as has been described above. Hence, because it becomes possible to avoid influences of heat from being given to the optical components 32 by applying an embodiment of the present invention, an embodiment of the present invention is quite effective in ensuring a high quality, a high reliability, and a high fabrication yield of the product.

It should be also noted that forming materials and forming dimensions of the respective components of the semiconductor device specified herein are mere examples to concretely implement an embodiment of the present invention. The understanding of the technical range of the present invention is therefore not limited by these examples.

It should be appreciated that the present invention is not limited by the contents described above and can be modified as the necessity arises without deviating from the scope of the invention.

The present application contains subject matter related to that disclosed in Japanese Priority Patent Application JP 2009-081097 filed in the Japan Patent Office on Mar. 30, 2009, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A manufacturing method of a semiconductor device comprising the steps of:
forming a component substrate of a semiconductor device provided with electrode pads on one surface thereof;
making via holes in a support plate material reinforcing the component substrate and filling a conducting material in the via holes; and
joining the component substrate and the support plate material in such a manner that the electrode pads on the component substrate and the conducting material filled in the via holes in the support plate material are electrically connected to each other.

2. The manufacturing method of a semiconductor device according to claim 1,
wherein the via holes are made as non-penetrating holes, and
the manufacturing method further comprises the step of making the support plate material thinner from a side of the support plate material after the joining step for the conducting material filled in the non-penetrating via holes to be exposed.

3. The manufacturing method of a semiconductor device according to claim 1 or 2, further comprising the steps of:
filling an insulating resin material in a clearance between the component substrate and the support plate material that have been joined; and
forming an outside wall portion surrounding a filling region of the insulating resin material before the insulating resin material filling step.

4. The manufacturing method of a semiconductor device according to claim 1, 2, or 3
wherein the semiconductor device is an imaging device formed by mounting an optical component on the component substrate, and
the optical component is mounted on the component substrate after the joining step.

5. A semiconductor device comprising:
a component substrate of a semiconductor device;
electrode pads provided on one surface of the component substrate;
a support plate material reinforcing the component substrate;
via holes made in the support plate material;
a conducting material filled in the via holes; and
a joining member interposed between the electrode pads and the conducting material and joining the component substrate and the support plate material.
